(19) United States
(12) Patent Application Publication
(10) Pub. No.: US 2006/0238210 A1
(43) Pub. Date: Oct. 26, 2006

(54) Interface and semiconductor testing apparatus using same

(75) Inventor: Akihiko Goto, Nishitama-gun (JP)

Correspondence Address: Paul D. Greeley;Ohlandt, Greeley, Ruggiero & Perle, L.L.P., One Landmark Square, 10th Floor, Stamford, CT, 06901-2682, US

(73) Assignee: Agilent Technologies, Inc.

(21) Appl. No.: 11/399,190

(22) Filed: Apr. 6, 2006

(30) Foreign Application Priority Data
Apr. 22, 2005 (JP) P2005-125081
Feb. 1, 2006 (JP) P2006-24466

(51) Int. Cl. G01R 31/02

(52) U.S. Cl. 324/754

(57) ABSTRACT

An interface (100) provided at a test head (13), for connecting a probe card (10) to the test head (13). Me interface includes an interface body (1), a coaxial connector (2) supported by the interface body (1), and an impelling mechanism (3) supported by the interface body (1) and impelling the probe card (10) in the direction of disjoining the coaxial connector (2) and a mating coaxial connector (15) provided at the probe card (10) in a state where the joining is implemented.

### TECHNICAL FIELD OF THE INVENTION

The present invention relates to an interface for mechanically connecting coaxial connectors to each other. In particular, the present invention relates to an interface for connecting a probe card to a test head via coaxial connectors and to a semiconductor test apparatus using such interface.

### BACKGROUND OF THE INVENTION

In a semiconductor test apparatus, inspection of semiconductor devices is conducted by bringing a probing needle of a probe card or a contact probe such as a membrane probe into contact with electrode pads of multiple semiconductor devices formed on a wafer, applying a test signal from a test head, and detecting output signals from the semiconductor devices.

The press recently achieved in the field of semiconductor devices that are the objects of measurement created a demand for improved performance of semiconductor test equipment. In particular, when measurements are conducted to determine the capacitance of gate insulating film, evaluate strain characteristics of transistors, and evaluate RF characteristics of transistors, the frequency of signals employed in the measurements extends to a HF band or RF band and measurements in the high-frequency bands become necessary.

Pogo pins are generally used for electric connection of a test head and a probe card in a semiconductor test apparatus. Pogo pins are also called connector pins, probe pins, and spring pins and they can maintain the measurement accuracy when used for measuring DC signals or low-frequency signals. However, when high-frequency signals in a HF band or RF band are measured, the measurement accuracy is difficult to maintain with the pogo pins due to a reflection loss or the like. According when high-frequency signals in a HF band or RF band are measured, coaxial connectors for HF or RF signals have to be used in the connection portions of the test head and probe card.

Engagement of coaxial connectors is usually conducted by manually attaching cal cables one by one to coaxial connectors. However, the applicant has invented and patented a connector that enables automatic engagement even of coaxial connectors (Japanese Patent Applications Laid-open No. 10-106677 and 10-107100).

### SUMMARY OF THE INVENTION

In the semiconductor test apparatuses described in Japanese Patent Applications Laid Open No. 10-106677 and 10-107100, a test head and a probe card are joined by a hinge. The coaxial connectors of the test head and probe card are disconnected by rising the test head via the hinge.

However, in the coaxial connectors used for measuring high-frequency signals in the RF band, the connection is established with strong joint force required to maintain the measurement accuracy. For this reason, the probe card is sometimes not separated from the test head even when the test head is raised via the hinge. The probe card is even more difficult to separate when the number of coaxial connectors is large.

The present invention was created to resolve the above-described problems and it is an object thereof to facilitate the disconnection of a test head and a probe card connected via coaxial connectors.

In order to achieve above object, the present invention provides an interface provided at a test head for connecting a probe card to the test head. The interface comprises an interface body, a coaxial connector supported by the interface body, and impelling device supported by the interface body, and impelling the probe card in the detection of disjoining the coaxial connector and a mating coaxial connector provided at the probe card in a state where the joining is implemented.

### BRIEF DESCRIPTION OF THE DRAWINGS

FIG. 1 is a schematic drawing illustrating the entire configuration of a semiconductor test apparatus;

FIG. 2 is a view of an interface 100 of the first embodiment of the present invention;

FIG. 3 is a plan view of an interface 100 of the first embodiment of the present invention;

FIG. 4 is a section view of an interface 100 of the first embodiment of the present invention;

FIGS. 5A and 5B illustrate the coaxial connector;

FIG. 6 is an exploded view of an impelling mechanism;

FIGS. 7A and 7B illustrate the operation of the interface 100 of the first embodiment of the present invention;

FIG. 8 is a schematic diagram of a semiconductor test apparatus 200 of the second embodiment of the present invention;

FIGS. 9A and 9B illustrate the operation of the semiconductor test apparatus 200 of the second embodiment of the present invention; and

FIGS. 10A and 10B illustrate another implementation mode of the impelling mechanism

### DESCRIPTION OF THE PREFERRED EMBODIMENTS

The embodiments of the invention will be described below with reference to the appended drawings.

### First Embodiment

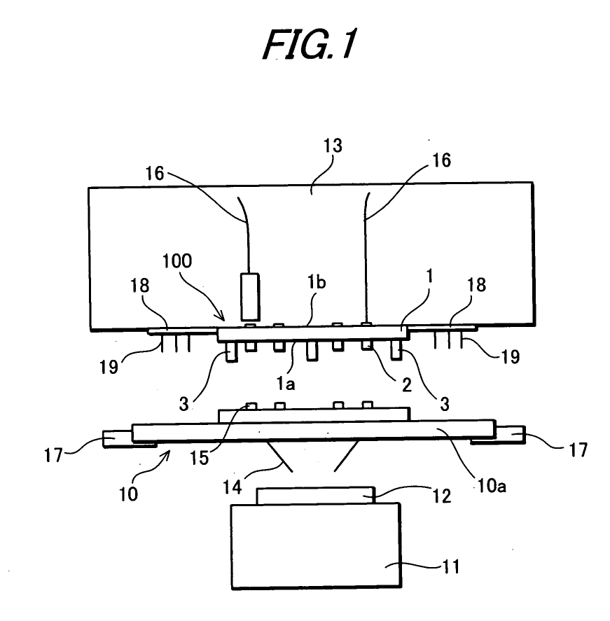

The interface 100 of the first embodiment will be explained below with reference to FIGS. 1 to 6.

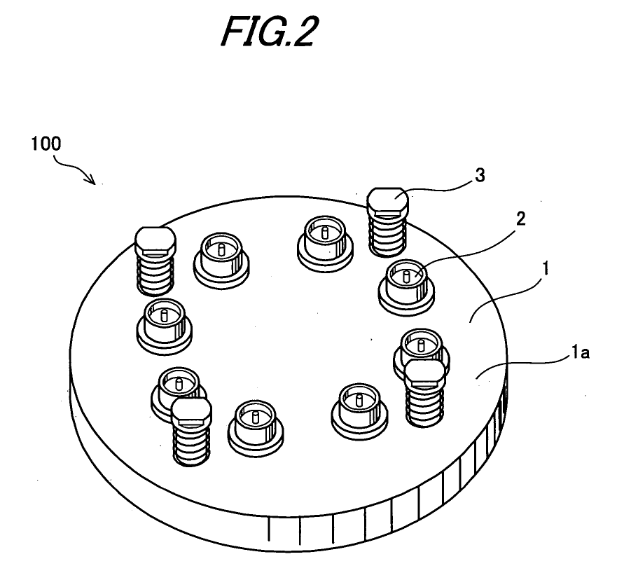

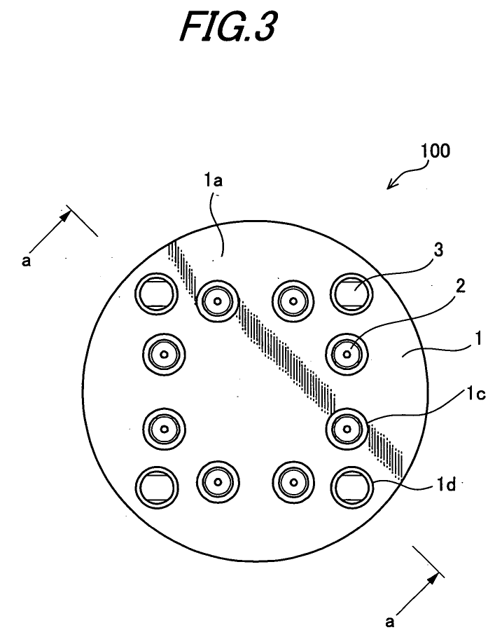

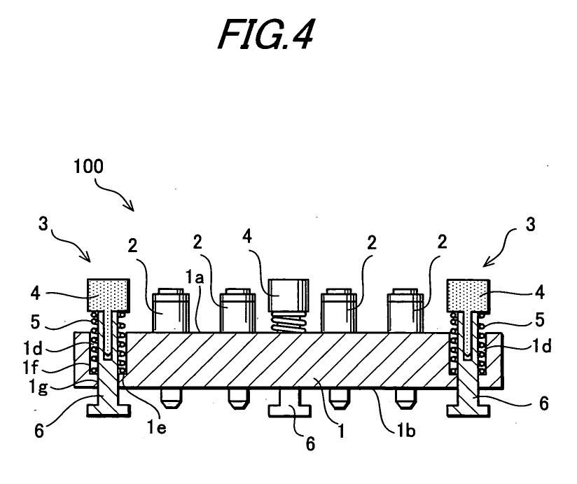

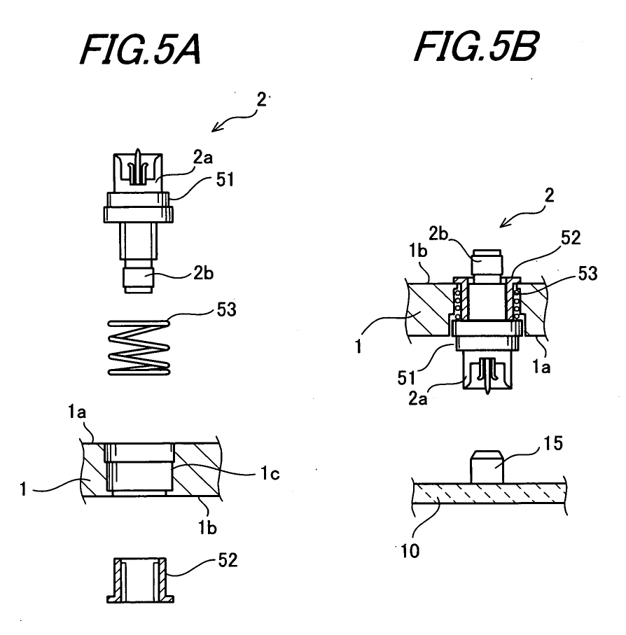

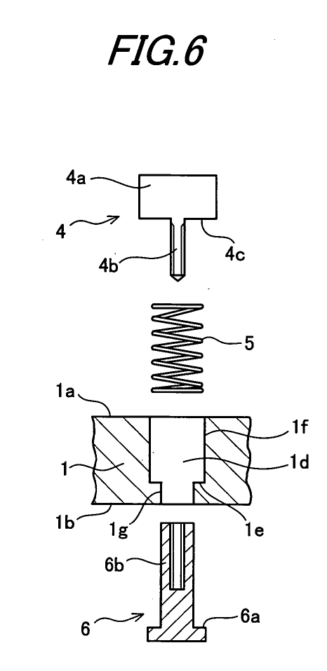

FIG. 1 is a schematic drawing illustrating a connection portion of a test head and a probe card of the semiconductor test apparatus. FIG. 2 is a perspective view of the in 100. FIG. 3 is a plan view of the interface 100. FIG. 4 is a cross-sectional view along the line a-a in FIG. 3. FIG. 5 illustrates a coaxial connector 2. FIG. 6 is an exploded view of an impelling mechanism 3.

The semiconductor test apparatus employing the interface 100 serves to inspect semiconductor devices formed on a wafer 12 which is a measurement object supported on a chuck 11. As shown in FIG. 1, the semiconductor test apparatus comprises a test head 13 for outputting electric signals to a semiconductor device, processing electric signals from the semiconductor device and measuring the electric characteristics of the wafer 12 and a probe card 10 comprising a probing needle 14 to be brought into contact with an electrode pad of the semiconductor device.

The test head 13 and probe card 10 are electrically connected by engaging coaxial connectors 2 provided at the interface 100 with mating coaxial connectors 15 provided at the probe card 10 and bringing a substrate section 10a of the probe card 10 into contact with pogo pins 19 disposed via an annular base plate 18 around the interface 100. The coaxial connector 2 serves for measuring a high-frequency signal and the pogo pin 19 serves to measure a low-frequency signal.

The interface 100 is provided at a test head 13 and s to connect the test head 13 to the probe card 10. The interface 100 comprises an interface body 1, a plurality of coaxial connectors 2, and an impelling mechanism 3 serving as impelling device for impelling the probe card 10 in the direction of disjoining the coaxial connectors 2 and mating coaxial connectors 15 in a state where the coaxial connectors 2 are joined to the mating coaxial connectors 15 of the probe card 10, that is, in a state where the test head 13 and probe card 10 are connected together.

A plurality of first through holes 1c and a plurality of second through holes 1d having respective openings at the first surface 1a facing the probe card 10 and the second surface 1b opposing the first surface 1a are provided in the interface body 1. In the present embodiment, the interface body 1 is shown to have a cylindrical shape for an example purpose, but this shape is not limiting.

The first through holes 1c support coaxial connectors 2, and the second through holes 1d support the impelling mechanism 3. The second through holes 1d comprise a large-diameter section 1f opened at the first surface 1a and a small-diameter section 1g open at the second surface 1b, as shown in FIG. 4 and FIG. 6, and a step 1e is formed at the inner peripheral surface thereof.

The coaxial connectors 2 will be described below with reference to FIG. 5A and FIG. 5B. FIG. 5A is an exploded view of the coaxial connector 2, and FIG. 5B illustrates a state where the coaxial connector 2 is attached to the interface body 1. The coaxial connector 2 serves to measure high-frequency signals, e.g., of a HF band or RF band and is disposed through the interface body 1.

A connector section 2a protruding from the first surface 1a of the interface body 1 is engaged with the mating coaxial connector 15 provided at the probe card 10, and a coaxial cable 16 leading to the test head 13 is connected to the connector section 2b protruding from the second surface 1b of the interface body 1.

In the coaxial connector 2, as shown in FIG. 5A, a blind mate connector 51 is supported via a flange nut 52 and a coil spring 53 in the first through hole 1c provided in the interface body 1. The blind mate connector 51 is configured to be capable of moving in the vertical direction and horizontal direction.

With such a configuration of the coaxial connectors 2, joining of the coaxial connectors 2 with the mating coaxial connectors 15 can be conducted by a snap-in system in which any of the coaxial connectors is pushed in the axial direction with respect to other coaxial connector, without rotating the two coaxial connectors 2 and 15 about the central axis. The joining force of a set of the coaxial connector 2 and the mating coaxial connector 15 is about 1 kgf. In FIGS. 5A and 5B, the connector section 2a is of a female connection type, and the mating connector 15 is of a male connection type, but the connector section 2a may be of a male connection type and the mating connector 15 may be of a female connection type.

As shown in FIG. 4 and FIG. 6, the impelling mechanism 3 comprises a push rod 4 serving as an impelling force transfer member for transferring the impelling force to the probe card 10, a coil spring 5 serving as an elastic member providing an impelling force to the push rod 4, and a guide 6 serving as a support member for holding the push rod 4 at the interface body 1.

The push rod 4 comprises a head 4a serving as an operation section for abutting against the probe card 10 and transferring the impelling force to the probe card 10 and a shaft section 4b for insertion into the second through hole 1d. The diameter of the head 4a is larger than the diameter of the large-diameter section 1f of the second through hole 1d. Furthermore, the diameter of the shaft section 4b is less than the diameter of the head 4a, and a step section 4c is formed at the boundary of the head 4a and shaft section 4b. A male thread is formed at the shaft section 4b.

The coil spring 5 is accommodated in the large-diameter section 1f in the second through hole 1d and disposed so that it can be compressed and extended between the step section 1e of the second through hole 1d and the step section 4c of the push rod 4.

The guide 6 comprises a collar section 6a with a diameter larger than the diameter of the small-diameter section 1g in the second through hole 1d, this collar section being provided at one end, and a shaft section 6b to be inserted into the second through hole 1d. A female thread is formed at the shaft section 6b.

A method for attaching various components of the impelling mechanism 3 to the interface body 1 will be explained below with reference to FIG. 6. First, the coil spring 5 is accommodated in the larger-diameter section 1f so that one end thereof abuts against the step section 1e in the second through hole 1d. Then, the shaft section 4b of the push rod 4 is inserted into the second through hole 1d from the side of the large-diameter section 1f. Then, the shaft section 6b of the guide 6 is inserted into the second through hole 1d from the side of the small-diameter section 1g, the male thread of the shaft section 4b and the female thread of the shaft section 6b are engaged, and the push rod 4 and guide 6 are joined together.

As a result, the joint body of the push rod 4 and guide 6 is inserted into the second through hole 1d and disposed so that it can slide with respect to the interface body 1. Furthermore, the coil spring 5 is disposed between the step section 1e and step section 4c at the circumference of the shaft section 6b. Furthermore, in the present embodiment, a configuration was explained in which the male thread was provided at the shaft section 4b and the female thread was provided at the shaft section 6b, but any configuration of the shaft section 4b and shaft section 6b may be employed, provided that the resultant structure makes it possible to join the push rod 4 and guide 6.

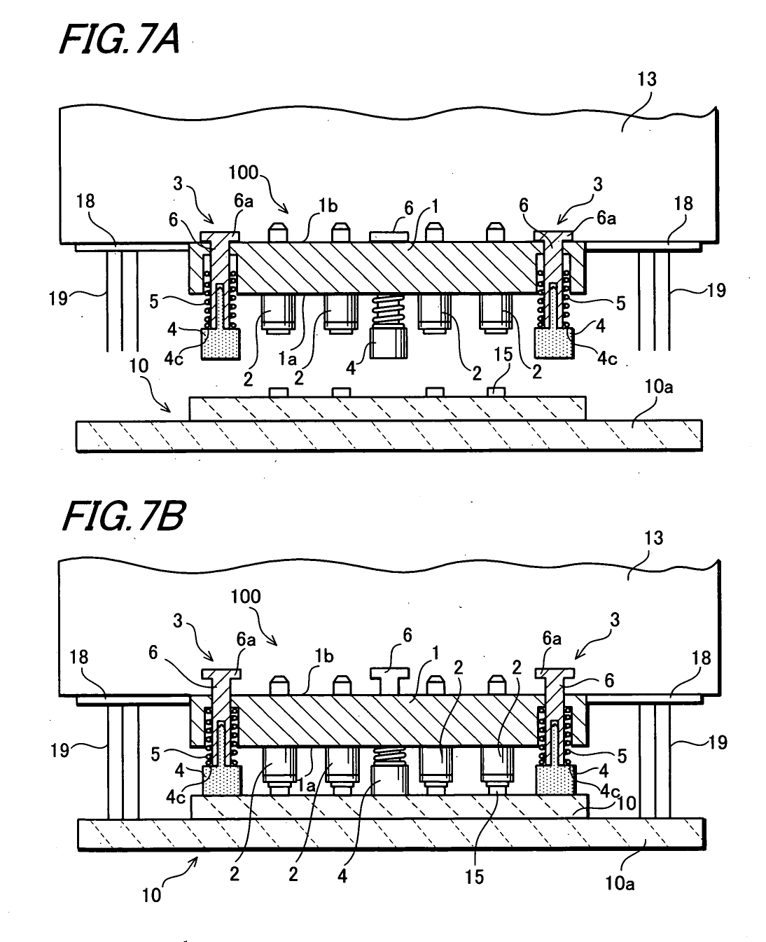

The operation and action of the interface 100 will be described below with reference to FIGS. 7A and 7B. FIG. 7A illustrates the state prior to connection of the test head 13 and probe card 10, and FIG. 7B shows a state where the test head 13 and probe card 10 have been connected by joining the coaxial connectors of the interface 100 and probe card 10.

First, as shown in FIG. 7A, the test head 13 and probe card 10 are disposed so that the coaxial connectors 2 of the test head 13 and the mating coaxial connectors 15 of the probe card 10 face each other.

Then, either the test head 13 or the probe card 10 is moved, the coaxial connectors 2 and the mating coaxial connectors 15 are joined together, as shown in FIG. 7B, and the test head 13 and probe card 10 are connected.

In this state, the coil spring 5 is compressed and disposed between the push rod 4 and interface body 1. Thus, the coil spring 5 impels the probe card 10 via the push rod 4 in the direction of disjoining the coaxial connectors 2 and mating coaxial connectors 15, that is, in the direction of disconnecting the test head 13 and probe card 10.

In order to disconnect the test head 13 and probe card 10, either the test head 13 or the probe card 10 is moved in the direction of disjoining the coaxial connectors 2 and mating coaxial connectors 15. At this time, because the coil spring 5 impels the probe card 10 in the direction of disjoining the coaxial connectors 2 and mating coaxial connectors 15, the test head 13 and probe card 10 can be easily disconnected by the action of the coil spring 5.

As described hereinabove, in a state where the coaxial connectors 2 of the test head 13 and the mating coaxial connectors 15 of the probe card 10 are joined, that is, in a state where the test head 13 and probe card 10 are connected, the probe card 10 is impelled in the direction of disjoining the coaxial connectors 2, 15. Therefore, with the first embodiment, the test head 13 and probe card 10 can be easily disconnected even in the case of coaxial connectors for high-frequency signal measurement that needs a strong joint force for high quality coupling.

The interface 100 is especially effective in the case where the number of coaxial connectors is large and the test head 13 and probe card 10 are difficult to disconnect.

### Second Embodiment

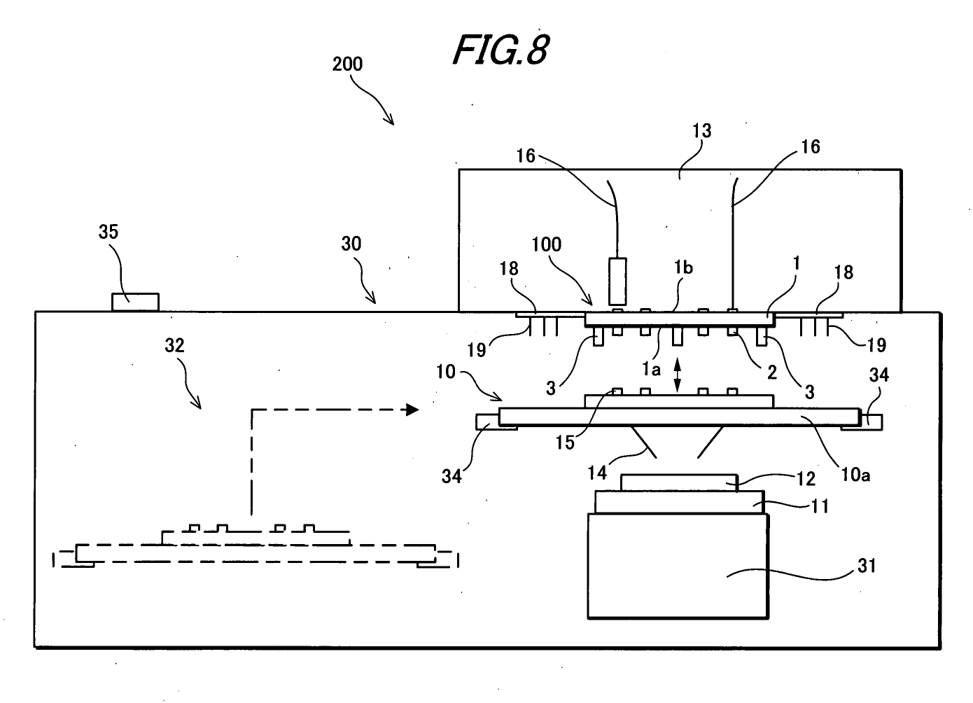

The semiconductor test apparatus 200, which is the second embodiment, will be described below with reference to FIG. 8. FIG. 8 illustrates schematically the semiconductor test apparatus 200.

The semiconductor test apparatus 200 comprises the interface 100 of the first embodiment for serving to connect the test head 13 and probe card 10 and conducts the inspection of the semiconductor device formed in the wafer 12 held in the chuck 11. The semiconductor test apparatus 200 is an apparatus enabling the automatic replacement of the probe card 10.

The test head 13 is fixedly disposed on the prober 30 where the probe card 10 is disposed. Thus, the probe card 10 is disposed below the test head 13. The prober 30 comprises a movement stage 31 that can move the chuck 11 holding the wafer 12 in the direction of X-Y-Z axes and a card changer 32 for conducting the replacement of probe card 10. The operation of the movement stage 31 and card changer 32 is controlled by the controller 35.

The card changer 32 comprises a support member 34 for supporting and transferring the probe card 10, and the support member 34 can be moved in the direction of X-Y-Z axes with a drive mechanism (not shown in the figure). The card changer 32 supports the desired probe card 10 supplied from a rack (not shown in the figure) accommodating a plurality of probe cards 10 and provided separately from the prober 30 on the support member 34 and transfers this probe card 10 to the inspection position. The probe card 10 is not fixed to the support member 34 and placed thereon under gravity.

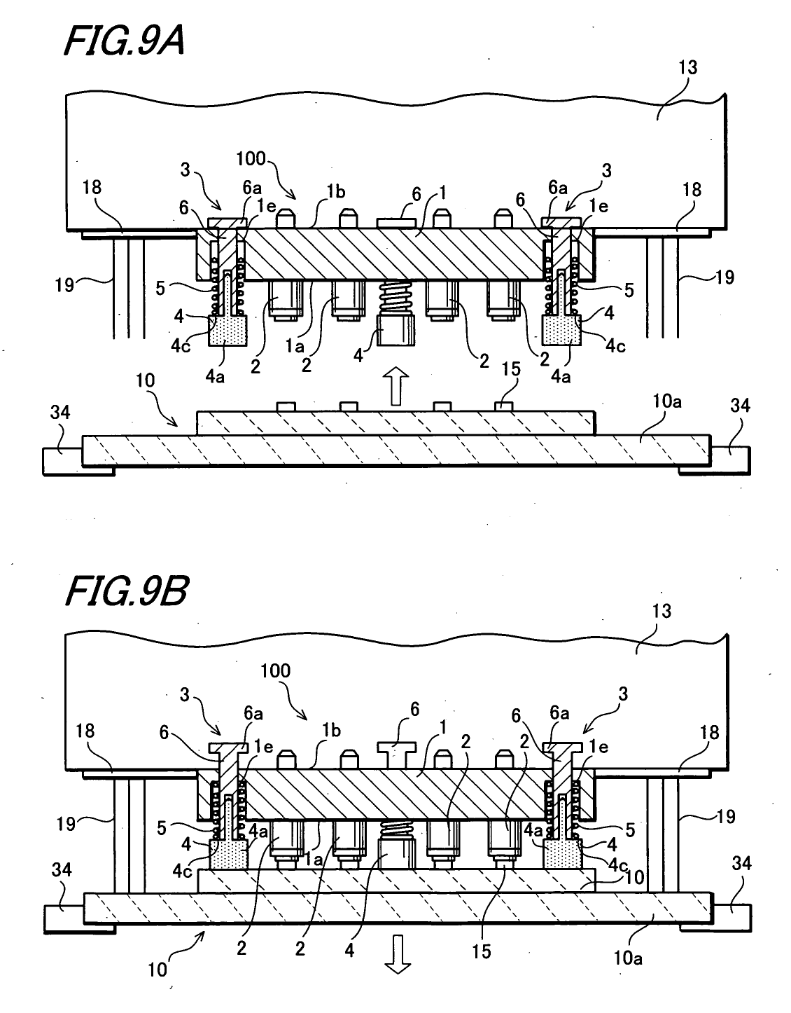

The operation and action of the semiconductor test apparatus 200 will be described below with reference to FIGS. 9A and 9B. FIG. 9A illustrates the state prior to connection of the test head 13 and probe card 10, and FIG. 9B shows a state where the test head 13 and probe card 10 have been connected by joining the coaxial connectors of the interface 100 and probe card 10.

First, the case where the test head 13 and probe card 10 are connected will be explained.

(1) As shown in FIG. 9A, the interface 100 is fixed to the test head 13 in a state where the first surface 1a faces downward. As a result, the joined body of the push rod 4 and guide 6 is suspended and held at the interface body 1 because the collar section 6a of the guide 6 abuts against the second surface 1b of the interface body 1. Furthermore, the coil spring 5 is positioned on the step section 4 of the push rod 4 and is in a state where no load is applied.

(2) The probe card 10 supported on the support member 34 is transferred by operating the support member 34 to below the interface 100 provided at the test head 13 and disposed so that the mating coaxial connectors 15 face the coaxial connectors 2.

(3) The probe card 10 is risen toward the interface 100 by the upward movement of the support member 34. As a result, as shown in FIG. 9B, the mating coaxial connectors 15 and coaxial connectors 2 are joined together, and the test head 13 and probe card 10 are connected.

(4) As the probe card 10 rises, the probe card 10 comes into contact with the head 4a of the push rod 4, and the joined body of the push rod 4 and guide 6 rises. As a result, the coil spring 5 is compressed between the step section 1e of the second through hole 1d and the step section 4c of the push rod 4.

(5) Because the coil spring 5 is compressed in a state where the test head 13 and probe card 10 are connected, the coil spring 5 constantly applies an impelling force to the push rod 4. As a result, the impelling force of the coil spring 5 is applied to the probe card 10 via the push rod 4. Thus, the coil spring 5 impels the probe card 10 in the direction of disjoining the mating coaxial connectors 15 and coaxial connectors 2, that is, downward. However, because the movement of the probe card 10 is controlled by the support member 34, the probe card 10 does not move.

The case where the test head 13 and probe card 10 are disconnected when the probe card 10 is replaced by operating the card changer 32 will be described below.

(1) In a state where the test head 13 and probe card 10 are connected, the support member 34 is lowered. In other words, the support member 34 is moved in the direction of releasing the impelling force of the coil spring 5. Because the support member 34 moves down, the control of the probe card 10 is released.

(2) The probe card 10 is not fixed to the support member 34, and the coaxial connectors 2 and mating coaxial connectors 15 are joined by a snap-in system. Therefore, as the support member 34 moves down, the weight of the probe card 10 acts as a driving force for disjoining the coaxial connectors 2, 15.

(3) Furthermore, the impelling force of the coil spring 5 is applied to the probe card 10 via the push rod 4. Thus, the coil spring 5 impels the probe card 10 in the direction of disjoining the coaxial connectors 2 and mating coaxial connectors 15, that is, downward. Therefore, the impelling force of the coil spring 5 also acts as a driving force for disjoining the coaxial connectors 2, 15.

(4) The coaxial connectors 2, 15 are disjoined by the weight of the probe card 10 and impelling force of the coil spring 5, and the test head 13 and probe card 10 are disconnected. Then, the probe card 10 is supported on the support member 34, transferred into the rack 33 by operating the card charger 32, and replaced with another probe card 10.

As described hereinabove, the semiconductor test apparatus 200 of the second embodiment comprises an interface 100 comprising the impelling mechanism 3, and the probe card 10 that is supported on the support member 34 and transferred is disposed below the test head 13. The disconnection of the test head 13 and probe card 10 is conducted by lowering the support member 34, that is, by moving it in the direction of releasing the impelling force of the impelling mechanism 3.

Therefore, with the second embodiment, when the probe card 10 is replaced by operating the card charger 32, the weight of the probe card 10 and the impelling force of the impelling mechanism 3 act as driving forces for disjoining the coaxial connectors 2, 15. Therefore, the probe card 10 can be easily from the test head 13 even in the case of coaxial connectors for high-frequency signal measurements with a high degree of coupling.

Furthermore, in the case of an apparatus for disconnecting the test head and probe card by raising the test head, as in the conventional semiconductor test apparatuses where the test head and probe card are joined with hinges, the probe card has to be replaced after the connection is released. Thus, the disconnection and replacement of the probe card have to be conducted as separate operations, and significant labor is required for replacing the probe card.

However, with the second embodiment, the test head 13 and probe card 10 can be disconnected by lowering the support member 34 in the process of replacing the probe card 10. Thus, the disconnection and replacement of the probe card 10 can be conducted in the same process. Therefore, the inspection of semiconductors can be conducted with good efficiency.

Furthermore, because the test head 13 and probe card 10 can be disconnected by merely lowering the support member 34, no special equipment is required for the disconnection, and the size of the semiconductor test apparatus itself can be reduced.

In the semiconductor test apparatus 200, the coaxial connectors 2 and mating coaxial connectors 15 are preferably disposed so as to be joined in the vertical direction. Such a disposition of the coaxial connectors 2, 15 makes it easier for the weight of the probe card 10 to act as a driving force for disjoining the coaxial connectors 2, 15 when the support member 34 is lowered and the test head 13 and probe card 10 are disconnected.

Another implementation mode of the impelling member 3 will be described below.

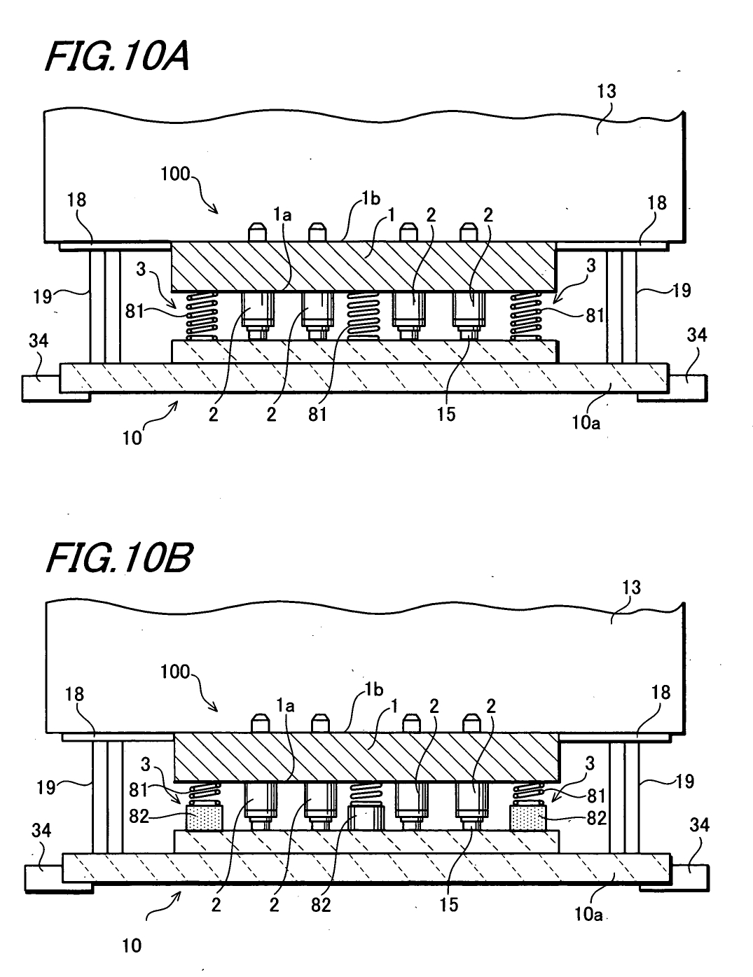

As another configuration of the impelling mechanism 3, as shown in FIG. 10A, the coil spring 81 serving as an elastic member may be disposed between the probe card 10 and interface body 1, and one end of the coil spring 81 may be directly attached to the interface body 1.

With such a configuration, in a state where the test head 13 and probe card 10 are connected to each other, the coil spring 81 is compressed by the probe card 10 and interface body 1. Therefore, the coil spring 81 impels the probe card 10 in the direction of disjoining the coaxial connectors 2, 15.

Furthermore, as shown in FIG. 10B, the impelling mechanism 3 of another configuration comprises a coil spring 81 as an elastic member and a push head 82 as an impelling force transfer member for transferring an impelling force to the probe card 10, one end of the coil spring 81 is directly attached to the interface body 1, and the other end is direct attached to the push head 82.

With such a configuration, in a state where the test head 13 and probe card 10 are connected to each other, the coil spring 81 is compressed by the push head 82 and interface body 1. Therefore, the coil spring 81 impels the probe card 10 via the push head 82 in the direction of disjoining the coaxial connectors 2, 15.

The present invention is obviously not limited to the above-described embodiment and can be modified in a variety of ways within the scope of the technical concept thereof.

For example, in the embodiments, a coil spring was used as an elastic member, but any elastic material for example rubber, may be used, provided that it applies and impelling force in a compressed state.

Furthermore, a membrane probe or other contact probe can be used instead of the probing needle.

What is claimed is:

1. An interface provided at a test head, for connecting a probe card to the test head, the interface comprising:
an interface body;
a coaxial connector supported by the interface body; and
impelling device supported by the interface body, and impelling the probe card in the direction of disjoining the coaxial connector and a mating coaxial connector provided at the probe card in a state where the joining is implemented.

2. The interface according to claim 1, wherein
the impelling device is an elastic member that can be compressed by the probe card and the interface body.

3. The interface according to claim 1, wherein
the impelling device comprises:
an impelling force transfer member for transferring an impelling force to the probe card; and
an elastic member that can be compressed by the impelling force transfer member and the interface body.

4. The interface according to claim 1, wherein
the impelling device comprises:
an impelling force transfer member for transferring an impelling force to the probe card;
an elastic member accommodated in a through hole provided in the interface body and compressible by a step provided at the inner peripheral surface of the through hole and the impelling force transfer member, and
a support member for supporting the impelling force transfer member at the interface body.

5. A semiconductor test apparatus in which a probe card can be replaced, comprising
the interface as defined in claim 1; and
a support member for supporting and transferring the probe card, wherein
the connection of the test head and the probe card is conducted by transferring the probe card by the support member so that the mating coaxial connector of the probe card is joined with the coaxial connector of the test head; and
the disconnection of the test head and the probe card is conducted by moving the support member in the direction of releasing the impelling force of the impelling device.

6. The semiconductor test apparatus according to claim 5, wherein
the probe card is disposed below the test head, and
the disconnection of the test head and probe card is conducted by lowering the support member in a state where the probe card is connected to the test head via the interface.

7. A method for connecting and disconnecting a test head and a probe card via an interface, wherein
the interface comprises an interface body provided at the test head, a coaxial connector supported by the interface body and serving for joining to a mating coaxial connector provided at the probe card, and impelling device supported by the interface body and impelling the probe card in the direction of disjoining the coaxial connector and the mating coaxial connector in a state where the joining is implemented, and wherein
the method comprises the steps of:
supporting the probe card at a support member for transferring the probe card;
connecting the test head and the probe card by transferring probe card by the support member so that the mating coaxial connector of the probe card joins to the coaxial connector of the test head; and
disconnecting the test head and the probe card by moving the support member in the direction of releasing the impelling force of the impelling device.

8. The method for connecting and disconnecting a test head and a probe card according to claim 7, wherein
the probe card is disposed below the test head; and
the test head and the probe card are disconnected by lowering the support member in a state where the probe card is connected to the test head via the interface.
